(19) United States
(12) Patent Application Publication
(10) Pub. No.: US 2023/0324312 A1
(43) Pub. Date: Oct. 12, 2023

(54) SYSTEM AND METHOD FOR DETERMINING CONTACT HEIGHT OF A PACKAGED CHIP

(71) Applicant: Vitrox Technologies Sdn. Bhd., Bandar Cassia (MY)

(72) Inventors: Heng Juan Tan, Simpang Ampat (MY); Ting Lik Wong, Permatang Damar Laut (MY); Chee Kit Loh, Batu Maung (MY); Kek Keong Kim, Permatang Pauh (MY); Khai Tze Seow, Butterworth (MY); Yi Ting San, Sungai Bakap (MY)

(73) Assignee: Vitrox Technologies Sdn. Bhd., Bandar Cassia (MY)

(21) Appl. No.: 17/959,027

(22) Filed: Oct. 3, 2022

(30) Foreign Application Priority Data
Apr. 8, 2022 (MY) PI2022001873

(51) Int. Cl. G01N 21/956; H04N 5/225; G06T 7/60; G06T 7/10; H04N 5/247

(52) U.S. Cl. CPC G01N 21/95623; H04N 5/2256; G06T 7/60; G06T 7/10; H04N 5/247; G06T 2207/10152; G06T 2207/20021

(57) ABSTRACT

A system and method that obtains contact heights of a packaged chip. In particular, the system includes a first light source for emitting direct light, a second light source for emitting structured light, two or more cameras pointed towards the packaged chip for capturing a first set of images of the packaged chip, and a second set of images of the packaged chip, and at least one processor that processes the first set of images and the second set of images captured by the cameras to determine contact heights of the packaged chip. The cameras capture the first set of images when the first light source emits direct light towards the packaged chip, and capture the second set of images when the second light source emits structured light towards the packaged chip.

### CROSS-REFERENCE TO RELATED APPLICATION

The instant application claims priority to Malaysia Patent Application Serial No. PI2022001873 filed Apr. 8, 2022, the entire specification of which is expressly incorporated herein by reference.

### FIELD OF THE INVENTION

The invention relates to the inspection of chip contacts. More particularly, the invention relates to a system and method for determining the contact heights of a packaged chip, especially for chips of a Ball Grid Array (BGA) package and Land Grid Array (LGA) package.

### BACKGROUND OF THE INVENTION

A packaged chip may refer to a semiconductor device having an integrated circuit in chip form moulded within a substrate package, having one or more exposed pads that allow for electrical flow to the integrated circuit. A packaged chip may be manufactured based on various types of packaging technologies with considerations for its intended application.

In particular, a packaged chip may refer to a type of semiconductor device having an integrated circuit in chip form moulded to be within a Ball Grid Array (BGA) package or Land Grid Array (LGA) package. These types of packaged chips are designed to be surface-mounted onto a circuit board through the use of a plurality of solder balls or solder pads. Before being surface mounted, the solder balls or solder pads are to be attached to the exposed pads of these types of packaged chips. As such, for this type of packaged chip, the solder balls or solder pads may be regarded as its contacts. With this, this type of packaged chip, having solder balls or solder pads attached thereto, may then be placed upon pads of a circuit board and soldered thereto through a reflow soldering operation.

For the solder ball or solder pad to be attached to this type of packaged chip, this type of packaged chip is exposed to low heat for the solder ball or solder pad to bond to its exposed pads. However, during this process, not all solder balls or solder pads may bond to this type of packaged chip properly, and thus the height of the solder balls or solder pads may vary. This may cause an overall unevenness across this type of packaged chip. As such, this type of packaged chip may not be fully attached to the printed circuit board during the reflow soldering operation. As such, systems and methods that allow for the determination of the contact heights of a packaged chip is crucial to minimize the failure rate of a final assembled circuit board.

There are a few disclosed technologies over the prior art relating to a system and method for measuring the contact height of a packaged chip. Among them is WO2010011124A, which discloses a method and means for measuring positions of contact elements of an electronic component that utilizes scaling factors in x, y and z dimensions. The scaling factors are determined during calibration procedures. In this prior art, a calibration operation maps image points recorded in the first camera for each point of the contact element to corresponding image point recorded in the second and third camera as part of the process to obtain a displacement between a first image point and a second image point to determine a height difference.

Another disclosed technology is US20100177192A1, which discloses a three-dimensional measuring device having an irradiation device that irradiates a structured light onto a measurement object, an imaging device that images reflected light from the measurement object irradiated by the light pattern to obtain image data, an image processing device that measures height at various coordinate positions on the measurement object based on the image data imaged by the imaging device, and a correction calculation device that performs distortion correction. In particular, it is noted that this disclosed technology uses four different pattern lights are used to measure contact height.

However, it is noted that no solutions were disclosed by the aforementioned prior arts that allow an accurate calculation of contact heights of the packaged device through the use of both direct light and structured light. Accordingly, it may be desirable to have a system and method for determining the contact height of a packaged chip, especially for chips of a Ball Grid Array (BGA) package and Land Grid Array (LGA) package. It is also preferable that one single pattern light is used so as to reduce inspection time.

### SUMMARY OF THE INVENTION

The main objective of the present invention is to provide a system and method for determining the contact heights of a packaged chip. To achieve this objective, the invention employs the use of direct light and structured light for determining the contact heights of a packaged chip. In particular, the direct light shall allow for a height between a contact of the packaged chip and a first reference point to be obtained, and the structured light shall allow for a height between a point on the package surface of the packaged chip and a second reference point to be obtained. The absolute difference between these heights shall allow for the determination of a contact height of the packaged chip.

As a result of this invention, the determination of the contact heights of a packaged chip has improved accuracy as heights of two or more distinct points on the packaged chip with reference to one or more reference points may be obtained for determining the contact heights. Moreover, the invention may be potentially be used for coplanarity tests in an inspection process.

The present invention intends to provide a system for determining contact heights of a packaged chip, comprising a first light source for emitting direct light, a second light source for emitting structured light, two or more cameras pointed towards the packaged chip for capturing a first set of images of the packaged chip and a second set of images of the packaged chip, and at least one processor that processes the first set of images and the second set of images captured by the cameras to determine contact heights of the packaged chip. The cameras capture the first set of images when the first light source emits direct light towards the packaged chip, and capture the second set of images when the second light source emits structured light towards the packaged chip.

Preferably, the processor operates one or more modules, which include a contact determination module, for deriving positions of one or more contacts of the packaged chip from the first set of images, a first height determination module, for deriving a first height based on a first relative measurement between the positions of the contacts of the packaged chip and a first reference point, a package surface determination module, for deriving one or more points along the package surface of the packaged chip from the second set of images, a second height determination module, for deriving a second height based on a second relative measurement between the points along package surface of the packaged chip and a second reference point, and a contact height determination module, for calculating contact heights of the packaged chip based on an absolute difference between the first height and the second height.

Preferably, the package surface determination module operated by the processor comprises one or more sub-modules that includes an image segmentation sub-module, for segmenting each image of the second set of images into one or more sub-images, a fringe determination sub-module, for determining bright fringe portions and dark fringe portions present within each sub-image, and a point designation sub-module, for assigning one or more designated points to be located within a centre of each dark fringe portions of the sub-image.

Preferably, the package surface determination module operated by the processor further comprises a first point-filtration sub-module, for filtering the one or more designated points for points that are located on, located close to, or both, a vertical centre line along the sub-image to remain.

Preferably, the second height determination module operated by the processor comprises one or more sub-modules, which includes a second point-filtration sub-module, for filtering the one or more designated points for points that are along the package surface of the packaged chip to remain.

Preferably, the camera includes a first camera, arranged perpendicularly with respect to the packaged chip, a second camera, arranged at a first angle with respect to the first camera and at a second angle with respect to the packaged chip.

The present invention also intends to provide a method for determining contact heights of a packaged chip, comprising the steps of pointing one or more cameras towards the packaged chip, emitting direct light, by a first light source, emitting structured light, by a second light source, capturing, by the cameras a first set of images of the packaged chip and a second set of images of the packaged chip, and processing, by at least one processor, the first set of images and the second set of images captured by the cameras to determine contact heights of the packaged chip. During the step of capturing, by the cameras, a first set of images of the packaged chip and a second set of images of the packaged chip, the cameras capture the first set of images when the first light source emits direct light towards the packaged chip, and capture the second set of images when the second light source emits structured light towards the packaged chip.

Preferably, the step of processing, by at least one processor, the first set of images and the second set of images captured by the cameras to determine contact heights of the packaged chip, further comprises the steps of deriving positions of one or more contacts of the packaged chip from the first set of images, by a contact determination module operated by the processor, deriving a first height based on a first relative measurement between the positions of the contacts of the packaged chip and a first reference point, by a first height determination module operated by the processor, deriving one or more points along package surface of the packaged chip from the second set of images, by a package surface determination module operated by the processor, deriving a second height based on a second relative measurement between the points along the package surface of the packaged chip and a second reference point, by a second height determination module operated by the processor, and calculating contact heights of the packaged chip based on an absolute difference between the first height and the second height, by a contact height determination module operated by the processor.

Preferably, the step of deriving one or more points along package surface of the packaged chip from the second set of images, by a package surface determination module operated by the processor further comprises the steps of segmenting each image of the second set of images into one or more sub-images, by an image segmentation sub-module of the package surface determination module, determining bright fringe portions and dark fringe portions present within each sub-image, by a fringe determination sub-module of the package surface determination module, and assigning one or more designated points to be located within a centre of each dark fringe portions of the sub-image, by a point designation sub-module of the package surface determination module.

Preferably, the step of deriving one or more points along package surface of the packaged chip from the second set of images, by a package surface determination module operated by the processor, further comprises the step of filtering the one or more designated points for points that are located on, located close to, or both, a vertical centre line along the sub-image to remain, by a first point-filtration sub-module of the package surface determination module.

Preferably, the step of deriving a second height based on a second relative measurement between the points along the package surface of the packaged chip and the pre-determined reference spaces, by a second height determination module operated by the processor, further comprises the step of filtering the one or more designated points for points that are along the package surface of the packaged chip to remain, by a second point-filtration sub-module of the second height determination module.

One skilled in the art will readily appreciate that the invention is well adapted to carry out the objects and obtain the ends and advantages mentioned, as well as those inherent therein. The embodiments described herein are not intended as limitations on the scope of the invention.

### BRIEF DESCRIPTION OF THE DRAWINGS

To facilitate an understanding of the invention, there is illustrated in the accompanying drawings the preferred embodiments from an inspection of which when considered in connection with the following description, the invention, its construction and operation and many of its advantages would be readily understood and appreciated.

FIG. 1 is a diagram illustrating the system of the present invention for determining contact heights of a packaged chip.

FIG. 2 is a diagram illustrating an example top view of the present invention.

FIG. 3a is a diagram illustrating a configuration of the present invention where the first lighting unit operates as a first light source that emits direct light towards the packaged chip.

FIG. 3b is a diagram illustrating a configuration of the present invention where the second lighting unit operates as a second light source emitting structured light towards the packaged chip.

FIG. 4a is a diagram illustrating a first image of the packaged chip of a first set of images, being an image captured by a first camera as the packaged chip receives direct light from a first light source.

FIG. 4b is a diagram illustrating a second image of the packaged chip of the first set of images, being an image captured by a second camera as the packaged chip receives direct light from the first light source.

FIG. 4c is a diagram illustrating a third image of the packaged chip of the first set of images, being an image captured by a third camera as the packaged chip receives direct light from the first light source.

FIG. 5a is a diagram illustrating a first image of the packaged chip of a second set of images, being an image captured by a first camera as the packaged chip receives structured light from a second light source.

FIG. 5b is a diagram illustrating a second image of the packaged chip of the second set of images, being an image captured by a second camera as the packaged chip receives structured light from the second light source.

FIG. 5c is a diagram illustrating a third image of the packaged chip of the second set of images, being an image captured by the third camera as the packaged chip receives structured light from the second light source.

FIG. 6 is a diagram illustrating a detailed block diagram of the computer that controls and manages the operation of the present invention.

FIG. 7 is a pictorial flowchart illustrating the designation and filtration of points on the package surface of the packaged chip.

FIG. 8a is a diagram illustrating mapped points in a first reference coordinate space.

FIG. 8b is a diagram illustrating mapped points in a second reference coordinate space.

FIG. 9 is a diagram illustrating views of the first camera as to its perception as per the first reference coordinate space, views of the second camera as to its perception as per the second reference coordinate space, and relative measurements between points on a reference calibrator and points on the packaged chip.

### DETAILED DESCRIPTION OF THE INVENTION

The present invention relates to a system and method for measuring one or more contact heights of a packaged chip. The invention may also be presented in a number of different embodiments with common elements. According to the concept of the invention, there is a holder unit in which a packaged chip is held thereon, one or more cameras pointing towards the packaged chip for capturing images of it at different angles, a lighting unit that acts as a first light source and a second light source, and a computer for processing images captured by the cameras so that contact heights of the packaged chip is determined.

The invention will now be described in greater detail, by way of example, with reference to the drawings.

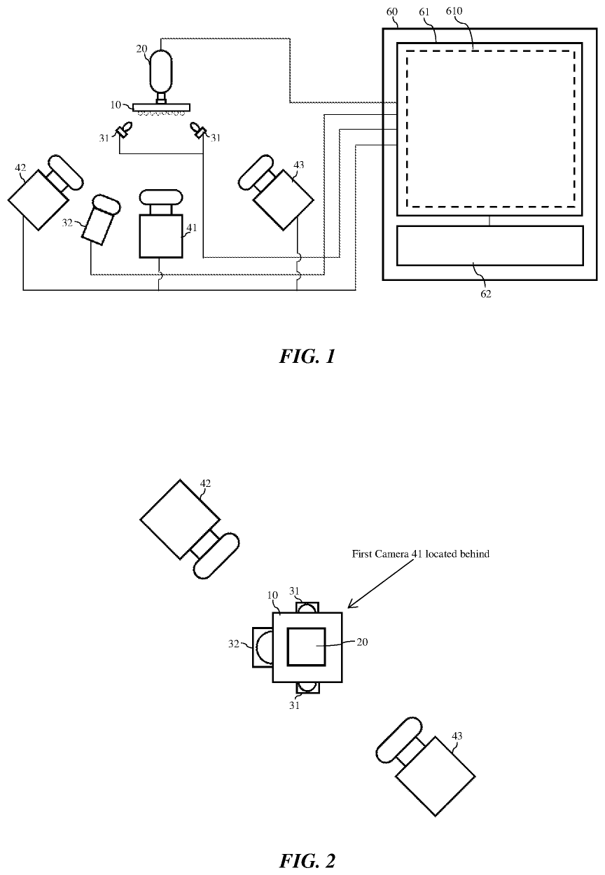

FIG. 1 illustrates the system of the present invention for determining one more contact heights H of a packaged chip 10. Preferably, the packaged chip 10 originates from a substrate packaging process. Most preferably, the packaged chip 10 is compatible with surface-mount technology with the packaged chip 10 having one or more solder balls attached thereto. These solder balls may be regarded as contacts of the packaged chip 10. Alternatively, these solder balls may be substituted with solder pads. As such, descriptions involving solder balls apply to solder pads as well.

Alternatively, the packaged chip 10 may originate from a lead frame packaging process and thus has leads as its contacts. It shall be noted that the packaged chip 10 may also originate from other related packaging processes such as chip-scale packaging, leaded packaging, leadless packaging, flip chip-ball grid array packaging, or the like. As such, it shall be understood that the description of the system and method of the present invention may be applicable for these kinds of packaged chips as well.

Referring to FIG. 1, the packaged chip 10 is held or supported in position, preferably in an upright manner by a holder unit 20. One or more lighting units 31, 32 emit light towards the packaged chip 10. One or more cameras 41, 42, 43, having their lenses pointed towards the packaged chip 10, may capture images of it at multiple views. A computer 60, having at least a processor 61, which runs an application software 610, and a memory unit 52, may then process these images for obtaining the contact heights H of the packaged chip 10.

Referring to FIG. 1, it should be noted that certain illustrated components, such as the packaged chip 10, the holder unit 20, the lighting units 31, 32, and the one or more cameras 41, 42, 43 were drawn to be perceived from a side view. FIG. 2 may be regarded as a complementary figure to FIG. 1, as it illustrates a top view of the packaged chip 10, the holder unit 20, the lighting units 31, 32, and the one or more cameras 41, 42, 43. With this, the arrangement of the packaged chip 10, the holder unit 20, the lighting units 31, 32, and the one or more cameras 41, 42, 43 may be described.

Referring to FIG. 1 and FIG. 2, it is noted that the holder unit 20 is arranged to be above the packaged chip 10 as it holds the packaged chip 10 in position. The holder unit 20 may be an end effector of a mechanical arm that preferably operates in a prismatic manner. The holder unit 20 is further equipped with a pickup tip that holds or support the packaged chip 10 in position through vacuum suction.

Referring to FIG. 1 and FIG. 2, it is noted that the lighting units 31, 32 are arranged to be below the packaged chip 10. Preferably, the lighting units 31, 32 are substantially pointed towards the bottom of the packaged chip 10 for light to be emitted towards it.

Referring to FIG. 1 and FIG. 2, it is noted that the cameras 41, 42, 43 are arranged to be below the packaged chip 10 with their lenses pointed towards it. The cameras 41, 42, 43 may be arranged to surround the packaged chip 10. The cameras include a first camera 41, a second camera 42, and a third camera 43.

In particular, it is noted that the first camera 41 is configured to be perpendicular with respect to the packaged chip 10, with its lens directly pointed towards it at an elevation angle of 90°. This is so that it may capture a “2-dimensional” image of the packaged chip 10. The second camera 42 may be arranged for it to be in a first angle with respect to the first camera 41 acting as a centre point, and its lens to be in a second angle with respect to the packaged chip 10. This second angle is a non-zero elevation angle, preferably of 45°. The third camera 43 may be arranged for it to be in a third angle with respect to the first camera 41 acting as a centre point, and its lens to be in a fourth angle with respect to the packaged chip 10. This fourth angle is a non-zero elevation angle, preferably of 45° as well. The arrangement of the second camera 42 and the third camera 43 are as such so that each of them may capture a “3-dimensional” image of the packaged chip 10. Preferably, as per FIG. 2, the cameras 41, 42, 43 are arranged to be in a straight line and are equidistant from each other.

In regards to the image sensors of the cameras 41, 42, 43, they may be active-pixel sensors fabricated using scientific complementary metal-oxide-semiconductor (sCMOS) technology. Alternatively, the image sensors of the cameras 41, 42, 43 may be of charge-coupled device (CCD) sensor technology. Moreover, the cameras 41, 42, 43 may use tilt-shift lenses for better image focusing.

In an alternative embodiment, only two cameras may be required for determining the contact heights H of the packaged chip 10, with one camera capturing a “2-dimensional” image of the packaged chip 10, and the other camera capturing a “3-dimensional” image of the packaged chip 10. As such, the third camera 43 or any additional cameras may be considered as supplementary cameras used to obtain more “3-dimensional” images of the packaged chip 10. Moreover, it is noted that the operation for determining the contact heights H of the packaged chip 10 based on the images captured by the first camera 41 and third camera 43 are the same as the operation for determining the contact heights H of the packaged chip 10 based on the images captured by the first camera 41 and second camera 42. Hence, the present invention may also be described using only the first camera 41 and the second camera 42.

In alternative embodiments of the present invention, mirrors may be included so as to overcome spatial constraints of the system. In particular, one or more angled mirrors are disposed between the second camera 42 and third camera 43 so that images of the packaged chip 10 may be reflected into the lenses of the cameras 42, 43. The usage of mirrors shall allow the second camera 42 and third camera 43 to cluster closer to the first camera 41, thereby reducing the space occupied by the cameras 41, 42, 43.

Referring to FIG. 1, the computer 60 may a conventional industrial computer. In regards to the processor 61 of the computer 60, it is preferably interfaced with the holder unit 20, the lighting units 31, 32, and the cameras 41, 42, 43. It shall perform the scheduling and the execution of software instructions or computer logic instructions as instructed by an application software 610 running thereon. Preferably, it may be, but shall not be limited to, a conventional processor, application-specific integrated circuit (ASIC), a field-programmable gate array (FPGA), or a combination thereof. In regards to the memory unit 62, it is preferably interfaced with the processor 61. The memory unit 62 may store program files related to the application software 610, or temporarily store processing data during runtime of the application software 610.

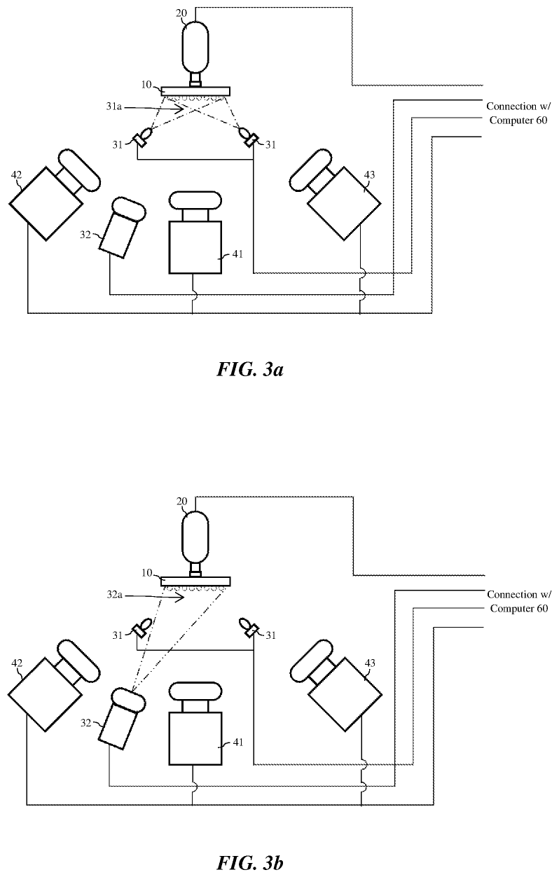

FIG. 3a illustrates an instance within the present invention where a first lighting unit 31 operates as a first light source that emits direct light 31a towards the packaged chip 10. Whereas, FIG. 3b illustrates another instance within the present invention where a second lighting unit 32 operates as a second light source that emits structured light 32a towards the packaged chip 10. In the context of the present invention, direct light 31a shall refer to a kind of light that is shined towards the packaged chip 10 without obstruction. Whereas, structured light 32a shall refer to a kind of light that is shined towards the packaged chip 10 that is obstructed by an object having one or more slits to create an alternating pattern of bright fringe portions and dark fringe portions on the packaged chip 10. Embodiments of the first lighting unit 31 may include a plurality of light-emitting diodes, whereas embodiments of the second lighting unit 32 may include a laser device, a projector, or a combination thereof. Whilst it is preferred that there are two separate lighting units 31, 32 with one acting as a first light source, and the other acting as a second light source, alternatively, both of these lighting units 31, 32 may be integrated into a single lighting unit that is capable of acting as both a first light source and a second light source.

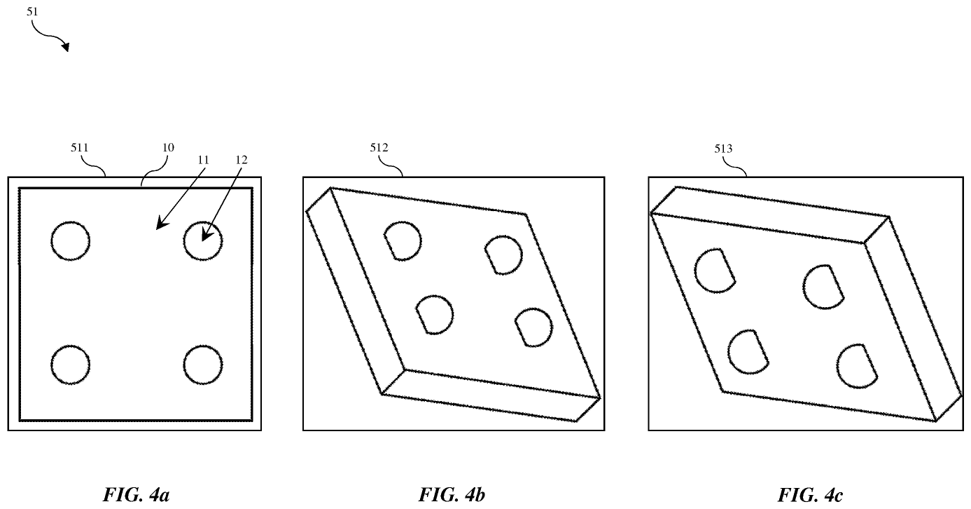

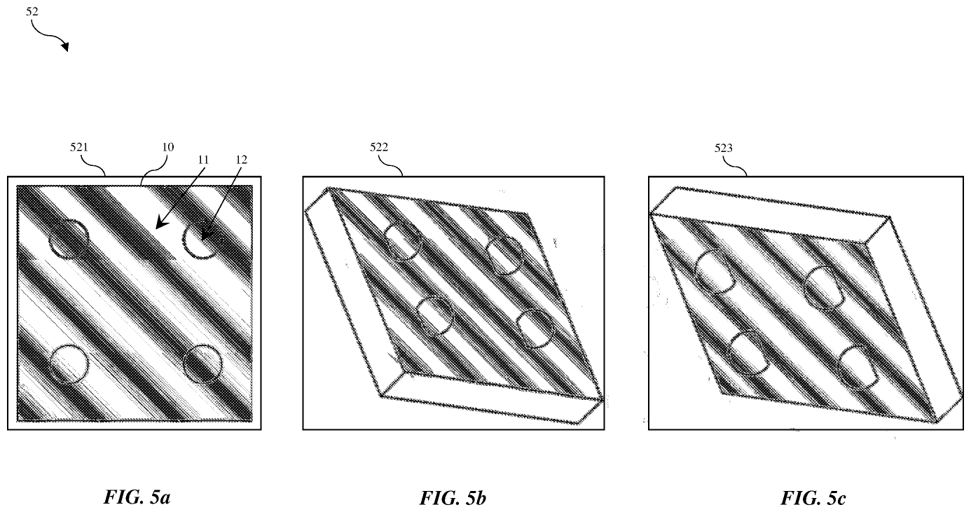

FIGS. 4a to 4c illustrate a first set of images 51 of the packaged chip 10 captured by the cameras 41, 42, 43. Seen from this first set of images 51 are contacts 11 and the package surface 12 of the packaged chip 10. Preferably, this set of images 51 is captured when the first lighting unit 31 emits direct light towards the packaged chip 10.

In particular, FIG. 4a illustrates a first image 511 of the packaged chip 10 of this first set of images 51, being an image captured by a first camera 41. FIG. 4b illustrates a second image 512 of the packaged chip 10 of this first set of images 51, being an image captured by a second camera 42. FIG. 4c illustrates a third image 513 of the packaged chip 10 of this first set of images 51, being an image captured by a third camera 43. In particular, due to the arrangement of the second camera 42 and third camera 43, said second image 512 and third image 513 are perspective views of the packaged chip 10.

FIGS. 5a to 5c illustrate a second set of images 52 of the packaged chip 10 captured by the cameras 41, 42, 43. Seen from these first set of images 52 include contacts 11 and the package surface 12 of the packaged chip 10. Preferably, this set of images 52 is captured when the second lighting unit 32 emits structured light towards the packaged chip 10. As such, each image of the packaged chip 10 in this second set of images 52 has alternating bright fringe portions and dark fringe portions.

In particular, FIG. 5a illustrates a first image 521 of the packaged chip 10 of this second set of images 51, being an image captured by a first camera 41. FIG. 5b illustrates a second image 522 of the packaged chip 10 of this second set of images 52, being an image captured by a second camera 42. FIG. 5c illustrates a third image 513 of the packaged chip 10 of this first set of images 52, being an image captured by a third camera 43. In particular, due to the arrangement of the second camera 42 and third camera 43, said second image 522 and third image 523 are perspective views of the packaged chip 10.

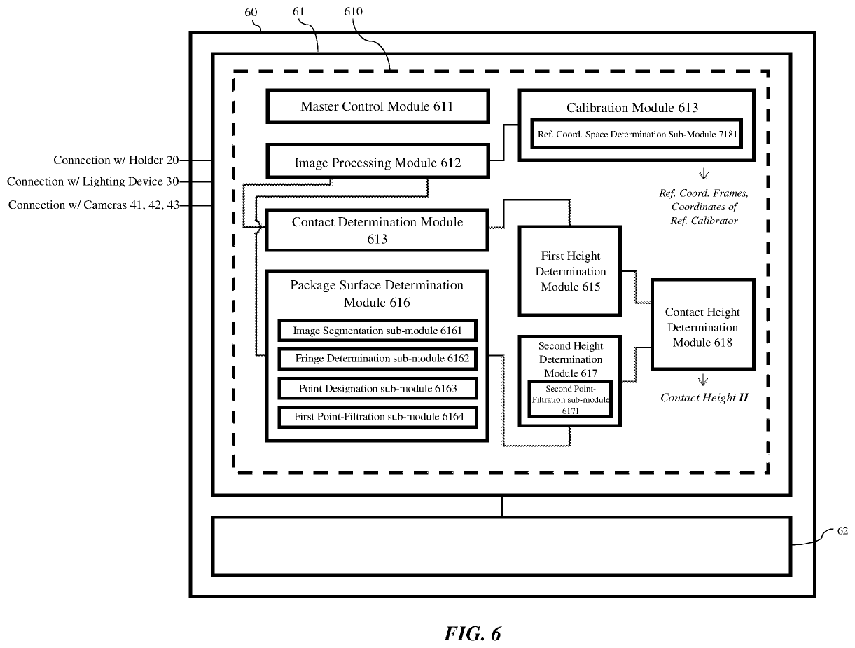

FIG. 6 illustrates a detailed block diagram representation of the computer 60 that controls and manages the operation of the present invention for determining contact heights H of a packaged chip 10.

Referring to FIG. 6, it may be said that processor 61 operates one or more modules. More particularly, these modules are software modules of the application software 610 that operates, or runs, on the processor 61 for computing algorithms and generating control instructions related to the operation of the system of the present invention. These modules may include a master control module 611, an image processing module 612, a calibration module 613, a contact determination module 614, a first height determination module 615, a package surface determination module 616, a second height determination module 617, and a contact height determination module 618. It should be noted that the presented modules need not be in a software embodiment, and may be a hardware embodiment where they are connected to the processor 61. Ancillary modules may be included to provide further support for the aforementioned modules.

Regarding the master control module 611 as shown in FIG. 6, it may preferably manage the operations of the holder unit 20, the lighting units 31, 32, and the cameras 41, 42, 43 through one or more control configurations.

In a first control configuration example, the master control module 611 may actuate the holder unit 20 to pick up a packaged chip 10 from a production batch and bring it over to a position per in FIG. 1 and FIG. 2. After images of the packaged chip 10 are captured, the master control module 611 may actuate the holder unit 20 to place away from the packaged chip 10 and pick up a succeeding one from the production batch.

In a second control configuration example, the master control module 611 may control the lighting units 31, 32 to switch between their operations. This is so that the first lighting unit 31 may emit direct light 31a at one instant, and that the second lighting unit 32 may emit structured light 32a at another instant.

In a third control configuration example, the master control module 611 may control the cameras 41, 42, 43 for them to simultaneously capture an image of the packaged chip 10.

In a fourth control configuration example, the master control module 611 may control the timing between the second control configuration and the third control configuration, so that the cameras 41, 42, 43 may immediately capture an image of the packaged chip 10 as each of the lighting units 31, 32 switch between their operations for the emission of direct light 31a towards the packaged chip 10 at one instant, and emission of structured light 32a towards the packaged chip 10 at one instant.

Regarding the image processing module 612 as shown in FIG. 6, it preferably pre-processes the images captured by the cameras 41, 42, 43 so that they may be primed to be processed by the subsequent modules. In particular, the image processing module 612 performs conventional image sharpening and image denoising algorithms onto the images. This may allow edges defining the contacts of the packaged chip 10, or bright fringe portions and dark fringe portions on the images, to be discerned.

Regarding the calibration module 613 as shown in FIG. 6, it serves to establish, or output, one or more reference coordinate spaces, which are preferably defined in terms of a coordinate system. Preferably, the calibration module 613 implements a calibration operation, and its description may be similar to the prior art WO 2010/011124 A1.

A summarized description of the calibration operation is as follows. A reference calibrator (not shown in FIG. 6), having reticules, is to be held or supported by the holder unit 20. The first lighting unit 31 may emit direct light 31a towards the reference calibrator. Then, cameras 41, 42, 43 may capture an image of the reference calibrator forming a set of calibration reference images. These calibration reference images, after being pre-processed by the image processing module 612, are to be processed by the calibration module 613 to generate a first reference coordinate space and a second reference coordinate space. From these reference coordinate spaces, a scale factor f, preferably being unitless, may be derived for scaling the reference coordinate spaces into real-world measurements. Moreover, the coordinates of the reference calibrator may be derived and mapped onto the reference coordinate spaces. This concludes the description of the calibration operation.

Based on a first image of the reference calibrator captured by the first camera 41, a reference coordinate space determination sub-module 6131 of the calibration module 613 may derive a first reference coordinate space, which is defined in terms of a Cartesian coordinate system.

Based on a second image of the reference calibrator captured by the second camera 42, the reference coordinate space determination sub-module 6131 of the calibration module 613 may derive a perspective projection of the first coordinate space, which shall henceforth be referred to as a second reference coordinate space, which is defined in terms of an affine-transformed Cartesian coordinate system or a projective-transformed Cartesian coordinate system. This is because the second image is a perspective view of the reference calibrator. Hence this second reference coordinate space includes depth information.

The inclusion of the third camera 43 (to capture the third image of the reference calibrator) or additional cameras may yield additional reference coordinate spaces of similar nature to the second reference coordinate space, but of a different perspective projection with respect to the first coordinate space instead. For simplicity, only the second reference coordinate space shall be described to be used. But it should be noted that descriptions regarding the second reference coordinate space may apply to the additional reference coordinate spaces derived due to the inclusion of the third camera 43 or additional cameras.

It shall be noted that a unique point within the first reference coordinate space may correspond to one or more unique points within the second reference coordinate space. Furthermore, said one or more unique points of the second reference coordinate space may be regarded as the orthogonally projected from the said unique point within the first reference coordinate space.

With this, the established reference coordinate spaces, together with coordinates of the reference calibrator, may then be permanently or temporarily stored in the memory unit 62 for them to be utilized later on by the other modules for obtaining the contact heights H of the packaged chip 10. It shall be noted that the reference calibrator may not necessarily be present when determining the contact heights H of the packaged chip 10 as its coordinates and dimensions are known by the system and any compensation for its presence is done through conventional means.

Regarding the contact determination module 614 as shown in FIG. 6, it serves to determine positional points of the contacts 11 of the packaged chip 10 that corresponds to a maxima, preferably being points on the solder balls that are furthest from the package surface 12 of the packaged chip 10. The contact determination module 614 preferably receives the pre-processed first set of images 51 from the image processing module 612. The contact determination module 614 may operate similarly to what was described in the prior art WO 2010/011124 A1. Alternatively, it may attempt to derive these points through an algorithm that determines these positions based on the casted shadows of the contacts 11 as perceived by the second camera 42 and third camera 43.

Regarding the first height determination module 615 as shown in FIG. 6, it serves to determine a height, or heights, between a contact 11 of the packaged chip 10 and the reference calibrator. This is done by mapping the first set of images 51, with the positional points of the contacts 11 having been determined, over the reference coordinate spaces and the coordinates of the reference calibrator previously stored in the memory unit 62.

In particular, the first height determination module 615 shall derive a first relative measurement ΔZ₁′, which is a measurement between the contact 11 and a first reference point of the reference calibrator in the second reference coordinate space. After obtaining the first relative measurement ΔZ₁′, the first height determination module 615 may then perform a multiplication operation between the first relative measurement ΔZ₁′ and the scale factor f to obtain a first height ΔZ₁ as a product. This first height ΔZ₁ corresponds to the actual height between a contact 11 of the packaged chip 10 and the first reference point of the reference calibrator in real-world measurements.

Regarding the package surface determination module 616 as shown in FIG. 6, it serves to determine points along the package surface 12 of the packaged chip 10. The package surface determination module 616 preferably receives the pre-processed second set of images 52 from the image processing module 612. It is further shown that the package surface determination module 616 comprises one or more sub-modules, which include an image segmentation sub-module 6161, a fringe determination sub-module 6162, a point designation sub-module 6163, and a first point filtration sub-module 6164.

In particular, the image segmentation sub-module 6161 of the package surface determination module 616 serves to segment each image of the second set of images 52 into one or more sub-images, preferably of a fixed area.

In particular, the fringe determination sub-module 6162 of the package surface determination module 616 may then receive each sub-image and determine dark fringe portions present therein. This may be done, for example, by algorithmically adjusting the contrast levels within each sub-image for the dark fringes portions to be accentuated. Preferably, after doing so, there is no ambiguity in the widths and lengths of the dark fringes portions across the sub-image.

In particular, the point designation sub-module 6163 of the package surface determination module 616 preferably assigns one or more designated points to be located within a centre of each dark fringe portion within the sub-image so as to mark them as potential points where the package surface 12 of the packaged chip 10 may be located. First, for each dark fringe portion, the point designation sub-module 6163 determines its pixels located along longitudinal edges are detected. Then, the point designation sub-module 6163 determines a centre pixel point of a dark fringe portion and assigns the designated point thereto. In a sense, the centre pixel point of the said dark fringe portion is said to be the “centre of gravity” of said dark fringe portion.

In particular, the first point filtration sub-module 6164 of the package surface determination module 616 preferably filters out the one or more designated points designated by the point designation sub-module 6163 for points that are closest to or located along a vertical centre line of the sub-image to remain. For this to be done, the first point filtration sub-module 6164 may algorithmically derive the edges of the sub-image to estimate a vertical centre line across package surface 12 within the sub-image. Preferably, designated points that are within an error margin of 2 pixels away from the vertical centre line are chosen to remain.

In the case where the sub-images originate from the second image 522 or the third image 523 within the second set of images 52, the vertical centre line may be transformed through affine transformations or perspective transformations so that it is substantially parallel to the corresponding perspective view of the packaged chip 10 as in the second image 522 or the third image 523.

Regarding the second height determination module 617 as shown in FIG. 6, it serves to determine a height, or heights, between a point along the package surface 12 of the packaged chip 10 and the reference calibrator. This is done by mapping the second set of images 52, with the designated points of the package surface 12 having been determined, over the reference coordinate spaces and the coordinates of the reference calibrator previously stored in the memory unit 62.

In particular, the second height determination module 617 shall derive a second relative measurement ΔZ₂′, which is a measurement between a point along the package surface 12 of the packaged chip 10 and a second reference point of the reference calibrator in the second reference coordinate space. After obtaining the second relative measurement ΔZ₂′, the second height determination module 617 may then perform a multiplication operation between the first relative measurement ΔZ₂′ and the scale factor f to obtain a second height ΔZ₂ as a product. This second height ΔZ₂ corresponds to the actual height between a point along the package surface 12 of the packaged chip 10 and the second reference point of the reference calibrator in real-world measurements.

It is further shown that the second height determination module 617 comprises one or more sub-modules, which includes a second point filtration sub-module 6171. The second point filtration sub-module 6171 serves to further filter designated points that were designated by the point designation sub-module 6163. It does so by calculating an error magnitude of the second height ΔZ₂ with reference to a plane defined by the first heights ΔZ₁ through a least mean squares algorithm. This serves to filter out the points along the package surface 12 that may have an error magnitude that is higher than or lower than a predetermined threshold. This error magnitude may have a range between 0 and 1. In a first example, should the error magnitude of a point be below a first predetermined threshold, said point shall be filtered out. In a second example, should 1 minus the error magnitude of a point be above a second predetermined threshold, said point shall be filtered out.

Regarding the contact height determination module 618 as shown in FIG. 6, it serves to calculate one or more contact heights H, a contact height H being the height between the contacts 11 of the packaged chip 10 and a point on the package surface 12 of the packaged chip 10. In particular, an absolute difference is calculated between the first height ΔZ₁ and the second height ΔZ₂. With this, the contact heights H of the packaged chip 10 are determined.

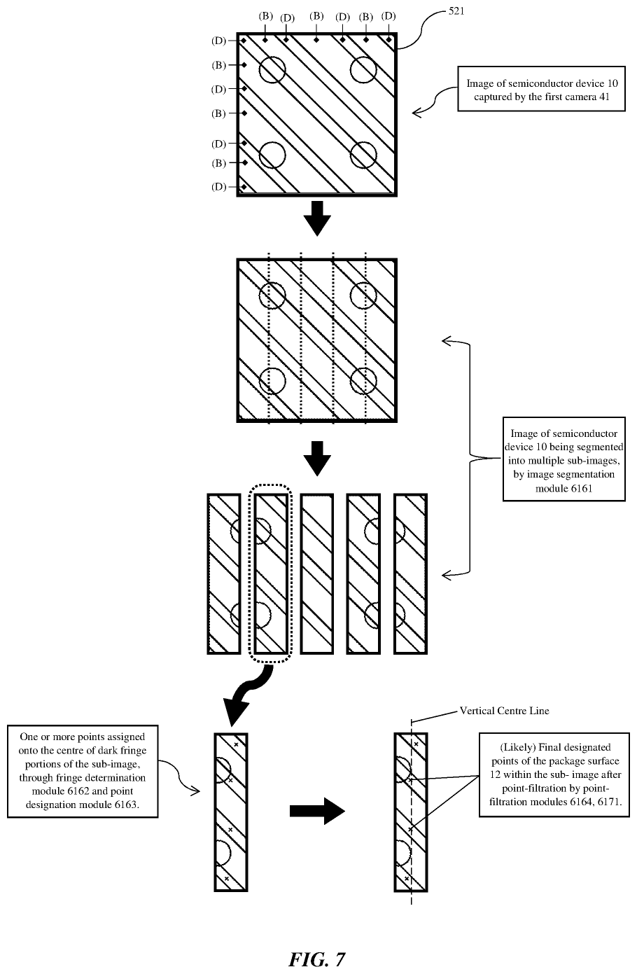

FIG. 7 is a pictorial flowchart illustrating designation and filtration of points on the package surface 12 of the packaged chip 10 performed by the package surface determination module 616. Preferably, this is done for all of the images within the second set of images 52. As an example, the first image 521 of the second set of images 52 is used. To illustrate the designation of designated points, this first image 521 is illustrated in such a way that its bright fringes are labelled as (B), and its dark fringes are labelled as (D).

After the first image 521 is pre-processed by the image processing module 611, the image segmentation module 6161 shall then segment the image into one or more sub-images of a fixed area, as shown. Then, one or more points are to be designated onto the dark fringe portions of the sub-image, by the fringe determination module 6162 and point designation module 6163. Finally, the designated points on the package surface 12 within the sub-image are filtered by the first point-filtration sub-module 6164 and the second point-filtration modules 6171 for final designated points within the sub-image to remain.

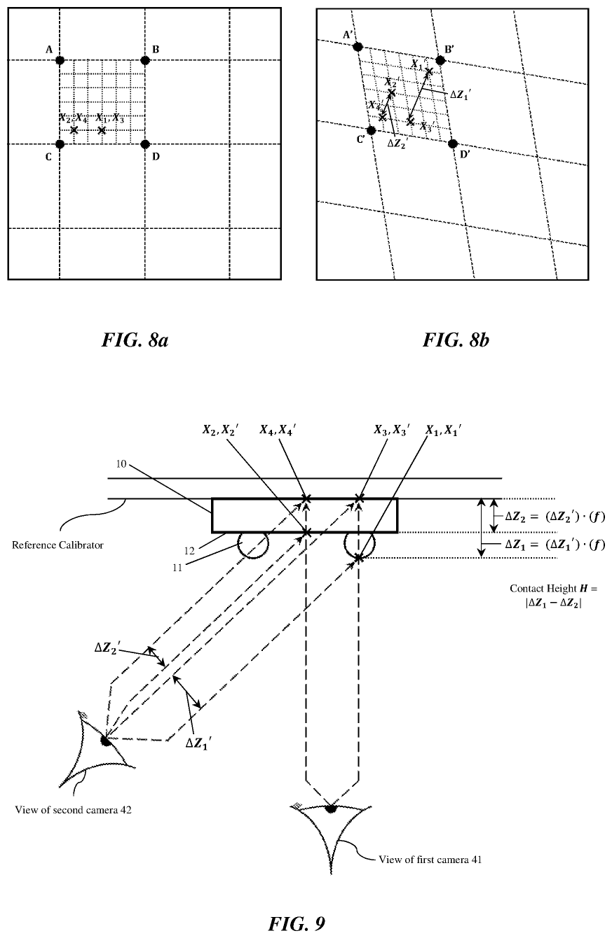

FIG. 8a illustrates mapped points in the first reference coordinate space, as per the perspective of the first camera 41. FIG. 8b illustrates mapped points in the second reference coordinate space, as per the perspective of the second camera 42. It should be noted that these illustrations are meant to illustrate the calculations that take place within the first height determination module 615 and the second height determination module 617.

FIG. 9 may be regarded as a complementary figure to FIG. 8a and FIG. 8b. It illustrates a viewing perspective of the first camera 41 as to the first reference coordinate space of FIG. 8a, a viewing perspective of the second camera 42 as to the second reference coordinate space of FIG. 8b, and relative measurements between points of the packaged chip 10 and the reference calibrator for the determination of a contact height H.

Referring to FIG. 8a and FIG. 9, within the first reference coordinate space, there is a grid cell ABCD. This grid cell ABCD has points X₁, X₂, X₃ and X₄ therewithin. It is noted that within this first reference coordinate space:

Point X₁ corresponds to a contact 11.

Point X₂ corresponds to a point on the package surface 12.

Point X₃ corresponds to a first reference point of the reference calibrator.

Point X₄ corresponds to a second reference point of the reference calibrator.

In particular, X₁ and X₃ may occupy the same coordinate position, while X₂ and X₄ may occupy the same coordinate position. Interpolation, more particularly, bilinear interpolation, with respect to the coordinates of the grid cell ABCD may be employed for the exact coordinates of the points X₁, X₂, X₃ and X₄ within the first reference coordinate space to be determined.

Referring to FIG. 8b and FIG. 9, within the second reference coordinate space, there is a grid cell A′B′C′D′. This grid cell A′B′C′D′ has points X₁′, X₂′, X₃′ and X₄′ therewithin. It is noted that within this second reference coordinate space:

Point X₁′ corresponds to a contact 11.

Point X₂′ corresponds to a point on the package surface 12.

Point X₃′ corresponds to a first reference point of the reference calibrator, orthogonally projected with respect to Point X₁′.

Point X₄′ corresponds to a second reference point of the reference calibrator, orthogonally projected with respect to Point X₂′.

As illustrated, the points X₁′, X₂′, X₃′ and X₄′ within the second reference coordinate space correspond to the points X₁, X₂, X₃ and X₄ of the first reference coordinate space. Similarly, interpolation with respect to the coordinates of the grid cell A′B′C′D′ may be employed for the exact coordinates of the points X₁′, X₂′, X₃′ and X₄′ within the second reference coordinate space to be determined. With the inclusion of depth information within this second reference coordinate space, there is now a distance between each of the points X₁′, X₂′, X₃′ and X₄′.

From this second reference coordinate space, the first relative measurement ΔZ₁′ between a contact 11 of the packaged chip 10 (being Point X₁′) and a first reference point of the reference calibrator (being Point X₃′) may be calculated. Also, the second relative measurement ΔZ₂′ between a point on the package surface 12 of the packaged chip 10 (being Point X₂′) and a first point of the reference calibrator (being point X₄′) may be calculated.

With that, the first relative measurement ΔZ₁′ and the second relative measurement ΔZ₂′ may then be multiplied using the scale factor f that was previously derived by the calibration module 613 to obtain the first height ΔZ₁ and the second height ΔZ₂.

As previously described, the first height ΔZ₁ is the actual height between a contact 12 of the packaged chip 10 and the first reference point of the reference calibrator in real-world measurements. The second height ΔZ₂ is the actual height between a point along the package surface 12 of the packaged chip 10 and the second reference point of the reference calibrator in real-world measurements.

The contact height determination module 618 shall then derive the contact height H between the contact 11 and the point on the package surface 12 by calculating an absolute difference between the first height ΔZ₁ and the second height ΔZ₂.

While not illustrated, a brief outline of the method of the present invention may be described. Preferably, prior to the steps of the method, a calibration operation is to be done for the establishment of the first reference coordinate space and the second reference coordinate space by the calibration module 613.

First, in Step 1, the holder unit 20 picks up a packaged chip 10 from a production batch and positions it as per FIG. 1 and FIG. 2.

In Step 2, the application software 610 may then operate the first lighting unit 31 to shine direct light 31a towards the packaged chip 10.

In Step 3, the application software 610 may direct the cameras 41, 42, 43 for each of them to capture an image of the packaged chip 10, thereby obtaining the first set of images 51. This first set of images 51 may be stored within the cameras 41, 42, 43 themselves.

In Step 4, the application software 610 may then operate the second lighting unit 32 to shine structured light 32a towards the packaged chip 10.

In Step 5, the application software 610 may direct the cameras 41, 42, 43 for each of them to capture an image of the packaged chip 10, thereby obtaining the second set of images 52. This second set of images 52 may be stored within the cameras 41, 42, 43 themselves.

In Step 6, the application software 610 may request the first set of images 51 and the second set of images 52 from the cameras 41, 42, 43.

In Step 7, the application software 610 may pre-process the first set of images 51 and the second set of images 52 using the image processing module 612.

In Step 8, the application software 610 may direct the pre-processed first set of images 51 into the contact determination module 614 for the position of contacts on the packaged chip 10 to be determined.

In Step 9, with the information from the prior step, Step 8, the first height determination module 615 calculates the first relative measurement ΔZ₁′ between the contact 11 and a first point of the reference calibrator in the second reference coordinate space, and then obtains the first height ΔZ₁. The first height ΔZ₁ is the actual height between a contact 12 of the packaged chip 10 and the first reference point of the reference calibrator in real-world measurements.

In Step 10, the application software 610 may direct the pre-processed second set of images 52 into the package surface determination module 614 for the points to be designated on the package surface of the packaged chip 10.

In Step 10.1, the image segmentation sub-module 6161 segments each image of the second set of images 52 into sub-images, preferably of a fixed area.

In Step 10.2, the fringe determination sub-module 6162 determines the bright fringe portions and the dark fringe portions within each sub-image obtained in the prior step, Step 10.1.

In Step 10.3, the point designation sub-module 6163 assigns one or more designated points located within a centre of each dark fringe portion of the sub-image.

In Step 10.4, the first point filtration sub-module 6164 filters the one or more designated points for points that were located on, located close to, or both, a vertical centre line along the sub-image to remain.

In Step 11, with the information from the prior step, Step 10.4, the second height determination module 617 calculates the second relative measurement ΔZ₂′ between the designated point on the package surface 12 and a second reference point of the reference calibrator, and then obtains the second height ΔZ₂, The second height ΔZ₂ is the actual height between a point along the package surface 12 of the packaged chip 10 and the second reference point of the reference calibrator in real-world measurements.

In Step 11.1, the second point filtration sub-module 6171 filters the one or more designated points by calculating an error magnitude of the second height ΔZ₂ with reference to a plane defined by the first heights ΔZ₁ through a least mean squares algorithm. This serves to filter out the points along the package surface 12 that may have an error magnitude that is higher than or lower than a predetermined threshold.

It should be noted that Steps 8 to 9 and Steps 10 to 11.1 may be executed serially or concurrently by the application software 610.

Finally, in Step 12, the contact height determination module 618 uses the information obtained from the prior steps Step 9 and Step 11.1 to determine a contact height H by calculating an absolute difference between the first height ΔZ₁ and second height ΔZ₂.

With this, the description of the system and method for determining the contact heights H of a packaged chip 10 is complete.

The present disclosure includes as contained in the appended claims, as well as that of the foregoing description. Although this invention has been described in its preferred form with a degree of particularity, it is understood that the present disclosure of the preferred form has been made only by way of example and that numerous changes in the details of construction and the combination and arrangements of parts may be resorted to without departing from the scope of the invention.

What is claimed is:

1. A system for determining contact heights of a packaged chip, comprising:
a first light source for emitting direct light;
a second light source for emitting structured light;
two or more cameras pointed towards the packaged chip for capturing a first set of images of the packaged chip; and
a second set of images of the packaged chip; and
at least one processor that processes the first set of images and the second set of images captured by the cameras to determine contact heights of the packaged chip;
wherein the cameras capture the first set of images when the first light source emits direct light towards the packaged chip; and
capture the second set of images when the second light source emits structured light towards the packaged chip.

2. The system according to claim 1, wherein the processor operates one or more modules, which include:
a contact determination module, for deriving positions of one or more contacts of the packaged chip from the first set of images;
a first height determination module, for deriving a first height based on a second relative measurement between the positions of the contacts of the packaged chip and a first reference point;
a package surface determination module, for deriving one or more points along the package surface of the packaged chip from the second set of images;
a second height determination module, for deriving a second height based on a second relative measurement between the points along package surface of the packaged chip and a second reference point; and
a contact height determination module, for calculating contact heights of the packaged chip based on an absolute difference between the first height and the second height.

3. The system according to claim 2, wherein the package surface determination module operated by the processor comprises one or more sub-modules, which include:
an image segmentation sub-module, for segmenting each image of the second set of images into one or more sub-images;
a fringe determination sub-module, for determining bright fringe portions and dark fringe portions present within each sub-image; and
a point designation sub-module, for assigning one or more designated points to be located within a centre of each dark fringe portion of the sub-image.

4. The system according to claim 3, wherein the package surface determination module operated by the processor further comprises a first point-filtration sub-module, for filtering the one or more designated points for points that are located on, located close to, or both, a vertical centre line along the sub-image to remain.

5. The system according to claim 4, wherein the second height determination module operated by the processor comprises one or more sub-modules, which includes a second point-filtration sub-module, for filtering the one or more designated points for points that are along the package surface of the packaged chip to remain.

6. The system according to claim 5, wherein the cameras include:
a first camera, arranged perpendicularly with respect to the packaged chip; and
a second camera, arranged at a first angle with respect to the first camera and at a second angle with respect to the packaged chip.

7. A method for determining contact heights of a packaged chip using a system according to claim 5, comprising the steps of:
pointing two or more cameras towards the packaged chip;
emitting direct light, by a first light source;
emitting structured light, by a second light source;
capturing, by the cameras, a first set of images of the packaged chip; and
a second set of images of the packaged chip; and
processing, by at least one processor, the first set of images and the second set of images captured by the cameras to determine contact heights of the packaged chip;
wherein, during the step of capturing, by the cameras, a first set of images of the packaged chip and a second set of images of the packaged chip, the cameras capture the first set of images when the first light source emits direct light towards the packaged chip, and capture the second set of images when the second light source emits structured light towards the packaged chip.

8. The method according to claim 7, wherein the step of processing, by at least one processor, the first set of images and the second set of images captured by the cameras to determine contact heights of the packaged chip, further comprises the steps of:
deriving positions of one or more contacts of the packaged chip from the first set of images, by a contact determination module operated by the processor;
deriving a first height based on a first relative measurement between the positions of the contacts of the packaged chip and a first reference point, by a first height determination module operated by the processor;
deriving one or more points along package surface of the packaged chip from the second set of images, by a package surface determination module operated by the processor;
deriving a second height based on a second relative measurement between the points along the package surface of the packaged chip and a second reference point, by a second height determination module operated by the processor; and
calculating contact heights of the packaged chip based on an absolute difference between the first height and the second height, by a contact height determination module operated by the processor.

9. The method according to claim 8, wherein the step of deriving one or more points along package surface of the packaged chip from the second set of images, by a package surface determination module operated by the processor, further comprises the steps of:
segmenting each image of the second set of images into one or more sub-images, by an image segmentation sub-module of the package surface determination module;
determining bright fringe portions and dark fringe portions present within each sub-image, by a fringe determination sub-module of the package surface determination module; and
assigning one or more designated points to be located within a centre of each dark fringe portion of the sub-image, by a point designation sub-module of the package surface determination module.

10. The method according to claim 9, wherein the step of deriving one or more points along package surface of the packaged chip from the second set of images, by a package surface determination module operated by the processor, further comprises the step of:
filtering the one or more designated points for points that are located on, located close to, or both, a vertical centre line along the sub-image to remain, by a first point-filtration sub-module of the package surface determination module.

11. The method according to claim 10, wherein the step of deriving a second height based on a second relative measurement between of the points along the package surface of the packaged chip and the pre-determined reference spaces, by a second height determination module operated by the processor, further comprises the step of:
filtering the one or more designated points for points that are along the package surface of the packaged chip to remain, by a second point-filtration sub-module of the second height determination module.
